(19) United States
(12) Patent Application Publication
(10) Pub. No.: US 2026/0143620 A1
(43) Pub. Date: May 21, 2026

(54) STRUCTURES FOR CONNECTING COMPONENTS IN NETWORKING ARCHITECTURES

(71) Applicant: Nexthop Systems Inc., Santa Clara, CA (US)

(72) Inventors: Harold Wang, Santa Clara, CA (US); Prasad Venugopal, Santa Clara, CA (US); Anshul Sadana, Santa Clara, CA (US)

(21) Appl. No.: 19/394,457

(22) Filed: Nov. 19, 2025

Related U.S. Application Data
(60) Provisional application No. 63/722,071, filed on Nov. 19, 2024.

(51) Int. Cl. H05K 7/14

(52) U.S. Cl. CPC H05K 7/1491; H05K 7/1417; H05K 7/1492

(57) ABSTRACT

A network architecture designed for efficiency and scalability. The assembly utilizes an orthogonal connection system where line cards and fabric cards are positioned orthogonally within physical infrastructure equipment including racks and modular data centers. The network architecture offers several advantages, including improved signal integrity, enhanced thermal management, and increased modularity. By eliminating the traditional backplane and utilizing direct connections, the network architecture reduces signal degradation and allows for better airflow, which is crucial for high-density systems. The modularity simplifies adding, removing, or upgrading components, making the network architecture easily adaptable to future needs.

### CROSS-REFERENCE TO RELATED APPLICATIONS

This application claims prior under 35 USC 119(e) to U.S. Provisional Application Ser. No. 63/722,071, filed on Nov. 19, 2024. U.S. Provisional Application Ser. No. 63/722,071 is hereby incorporated by reference in its entirety.

### BACKGROUND

Networking architectures generally include several different kinds of components, such as computer hardware (servers, processors, memory units, etc.), networking hardware (switches, routers, firewalls, cables, etc.), power and cooling hardware (Uninterruptible Power Supplies (UPS), Power Distribution Units (PDUs), Computer Room Air Conditioners (CRACs), cooling towers), and physical infrastructure (racks, cable management systems, raised floors, security systems, etc.). Racks provide a framework for organizing and housing the computer hardware, the networking hardware, the power and cooling hardware, and other equipment. Racks themselves can be configured in several different forms such as enclosed server racks/cabinets, wall-mounted racks, enclosed server cabinets with enhanced cooling, Open Rack (OR) configuration, etc. The OR configuration is a specific approach to designing and building data center infrastructure that emphasizes efficiency, scalability, and openness. The OR is a standard driven by the Open Compute Project (OCP), a community of technology leaders working together to create more efficient and sustainable data center solutions. The OR configuration uses a relatively wider and deeper rack and a larger vertical unit compared to traditional solutions to allow better airflow and cable management. Furthermore, the OR configuration facilitates modularity and hot swapping.

The networking and computing hardware is generally installed horizontally (parallel to the ground) or vertically (perpendicular to the ground) in the racks or modular data centers. The installed networking and computing hardware may include server sleds, line cards, fabric cards, Graphics Processing Units (GPUs), accelerators, power shelves, etc. However, as cloud-computing and telecommunication move into higher data transmission speeds, (for example, due to the implementation of artificial intelligence (AI) and higher generations of mobile communication standards) physical distances between the installed components (for example, line cards and fabric cards) become an impenetrable barrier.

Existing solutions broadly fall under two categories: cable cartridges and optical backplanes, both of which have severe limitations. For example, cable cartridges require specialized manufacturing setup, are susceptible to supply chain disruptions, are susceptible to physical damage in the field, and are hard to operate and replace in the field. Furthermore, optical backplanes are expensive and draw significantly large amounts of power.

Therefore, there is a need for improved assemblies and structures for minimizing data transmission distances between the connected components in networking architectures.

### BRIEF DESCRIPTION OF THE FIGURES

Certain embodiments will be described with reference to the accompanying drawings. However, the accompanying drawings illustrate only certain aspects or implementations of the disclosure by way of example and are not meant to limit the scope of the claims.

FIG. 1A illustrates a partial perspective view of an assembly of networking and computing components assembled in physical infrastructure equipment, in accordance with one or more embodiments.

FIG. 1B illustrates a detailed view of a portion of the assembly of FIG. 1A, in accordance with one or more embodiments.

FIG. 2 illustrates a side view of an assembly of networking and computing components assembled in physical infrastructure equipment, in accordance with one or more embodiments.

### DETAILED DESCRIPTION

Traditionally, connections between the fabric cards and the line cards (e.g., within network switches) involve complex components like cable cartridges and optical backplanes, which can be expensive and difficult to manage. However, cable cartridges generally require a specialized manufacturing setup, which increases costs, are further susceptible to supply chain distributions and physical damage in the field and are hard to operate and replace in the field. Optical backplanes, on the other hand, are expensive and draw significantly more power.

Embodiments of the disclosure propose a simpler and more efficient approach by directly connecting line cards to the fabric cards using edge connectors and overlay cables. For example, a fabric card can connect directly to an active line card (e.g., an active Application Specific Integrated Circuit (ASIC)) using a first edge connector. The active ASIC connects with the first edge connector through a plurality of active overlay cables. The same fabric card can further connect to a passthrough line card (i.e., a line card without an active ASIC) using a second edge connector. The fabric card includes a fabric ASIC that connects to both the first and the second edge connectors through a plurality of fabric overlay cables. Furthermore, the line cards (including the active line cards and the passthrough line cards) and the fabric cards are connected orthogonally. The orthogonal connections between the line cards and the fabric cards can also be extended to the Open Rack (OR) configuration. This means that, for example, if the line cards are installed horizontally, the fabric cards are installed vertically, and vice versa. There are several advantages of connecting the line cards and fabric cards orthogonally, especially in OR configuration.

For example, connecting the line cards and fabric cards orthogonally improves signal integrity. Direct connections minimize trace length and reduce the number of connectors between the line cards and the fabric cards. This leads to less signal degradation, lower latency, and improved overall performance, particularly at higher speeds. In another example, the orthogonal arrangement provides enhanced thermal management by allowing better airflow, which is crucial for cooling high-density systems. Heat dissipation is more efficient, preventing overheating and ensuring system stability. In yet another example, the orthogonal arrangement provides increased scalability and modularity. The described embodiments simplify the adding or removing of line cards and fabric cards, making it easier to scale the network up or down as needed. This modularity also provides flexibility for future upgrades and expansions. In yet another example, the orthogonal arrangement reduces complexity and cost by eliminating optical backplanes; orthogonal architectures can simplify system design and lower manufacturing costs. Further leading to easier maintenance and troubleshooting. In yet another example, the orthogonal arrangement optimized space utilization. That is, Open Rack configurations, combined with the orthogonal layout, can lead to more efficient use of rack space, allowing for higher density deployments and reduced footprint.

Furthermore, the use of passthrough line cards allows for front-facing only networking ports to be provided in the fabric cards. The front-facing only networking ports on the fabric cards in networking architectures offer several advantages in terms of serviceability, cable management, and airflow.

Another exemplary advantage of the disclose is improved accessibility. Specifically, the front-facing networking ports of the fabric cards allow technicians to easily access and connect cables to the passthrough line cards in the front portion of the rack, where the passthrough line cards are then connected, in the back portion of the rack, to the fabric cards through edge connectors. This makes it simpler to add, remove, or replace fabric cards, troubleshoot connections, and perform maintenance tasks. In another example, the front-facing networking ports reduce downtime. With easier access, maintenance and upgrades of a resultant network architecture can be performed more quickly, minimizing network downtime and disruptions. In yet another example, the front-facing networking ports provides for organized cabling. Cables connected in the front portion of the rack would make it easier to organize and manage cables, reducing clutter and improving airflow within the rack. In yet another example, the front-facing networking ports allow for cables to be labeled and identified more easily, simplifying network tracing and troubleshooting. In yet another example, the front-facing networking ports provide for reduced cable lengths. In many cases, the front-facing only networking ports of the fabric cards would lead to shorter cable runs, reducing cable congestion and signal degradation. In yet another example, the front-facing networking ports provide for improved cooling by keeping the rear of the rack clear, the front-facing networking ports would promote better airflow, which is essential for cooling high-density networking equipment. In yet another example, the front-facing networking ports provide for reduced hot spots in the assembly. Organized cabling and improved airflow can help prevent hot spots within the rack, ensuring consistent operating temperatures for all components. In yet another example, the front-facing networking ports provide for efficient space utilization: The front-facing networking ports can contribute to higher-density deployments by allowing for closer spacing between racks and maximizing the use of available space.

Also, several components of the fabric cards (such as ASICs, Field Programmable Gate Arrays (FPGAs), network processors, memory units, Serializer/Deserializer (SerDes), clocking devices, traffic management units, power management ICs, monitoring and control circuits, connectors, heat sinks, and cooling systems, etc.) are relatively easily accessible either from the side or from the top. This allows the components of the fabric cards to be easily maintained, diagnosed, repaired, upgraded, and/or replaced.

Various embodiments of the present disclosure provide assemblies and structures for minimizing data transmission distances between components in networking architectures. The components may include networking and computing hardware such as server sleds, line cards, fabric cards, Graphics Processing Units (GPUs), accelerators, power shelves, etc. The networking and computing hardware may be installed in physical infrastructure equipment such as enclosed server racks/cabinets, wall-mounted racks, enclosed server cabinets with enhanced cooling, Open Rack (OR) configuration, modular data centers, etc. The OR configuration, driven by the Open Compute Project (OCP), emphasizes efficiency, scalability, and openness. The OR configuration features standardized dimensions, efficient power distribution using busbars and power shelves, optimized airflow management, organized cable routing, and modular, hot-swappable components.

Thus, embodiments of the present disclosure focus on improving the connection between line cards, and fabric cards. Traditionally, these connections involve complex and costly components like cable cartridges and optical backplanes. The present disclosure proposes a more streamlined approach by connecting the line cards, located in the front portion of the physical infrastructure equipment, to the fabric cards in the rear portion, eliminating the need for intermediary components.

Furthermore, the line cards (e.g., active line cards and passthrough line cards) and the fabric cards are connected orthogonally to each other. For example, if the line cards are installed horizontally, the fabric cards are installed vertically, and vice versa. The orthogonal orientation allows a single fabric card to connect to multiple line cards using edge connectors and overlay cables. As will be discussed in conjunction with the figures, a fabric card may be directly connected to an active line card and a passthrough line card using edge connectors. The edge connectors can be high-speed, high-density types like PCIe or custom-designed for specific needs. The respective ASICs of the active line card and the fabric card communicate via the edge connectors and overlay cables. This eliminates the need for a backplane or midplane, reducing the distance between components and overcoming the limitations of traditional backplane cable designs. The passthrough line card further enhances the design by enabling the use of front-facing only network ports in fabric cards, making the fabric cards easier to service and/or replace. The embodiments discussed in the present disclosure offer a more efficient and cost-effective way to connect line cards to fabric cards in the networking architectures. By utilizing direct connections and an orthogonal arrangement, the embodiments simplify the implementation, reduce costs, improve scalability, and enhance maintainability.

Therefore, compared to traditional methods, embodiments disclosed herein offer several advantages such as lower costs (eliminates the need for expensive optical backplanes), reduced complexity (simplifies installation and cable management when compared with cable cartridges), better safety and operability (minimizes the risk of cables getting entangled and difficult to service), and improved scalability (allows for easy expansion to accommodate greater network bandwidth by adding more fabric cards).

The following describes various embodiments disclosed herein.

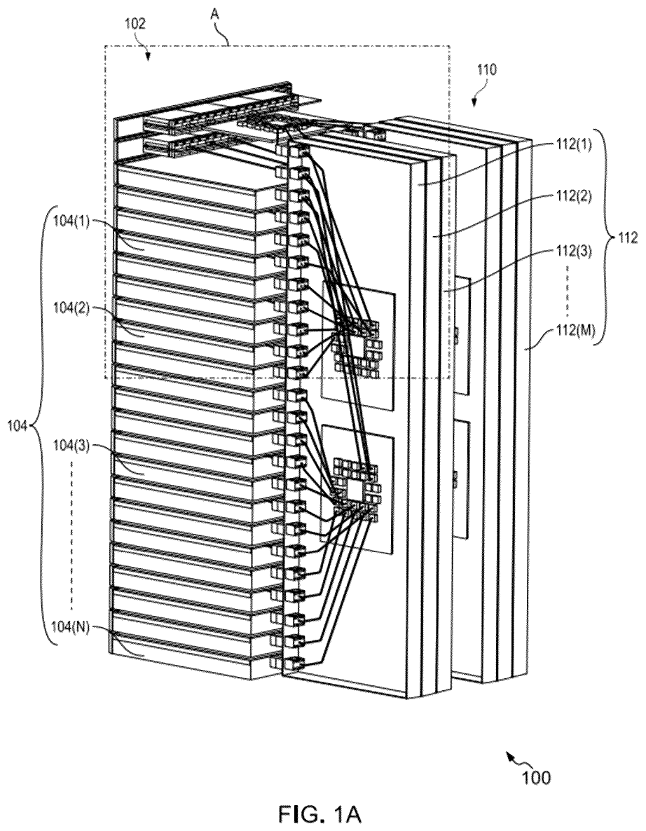

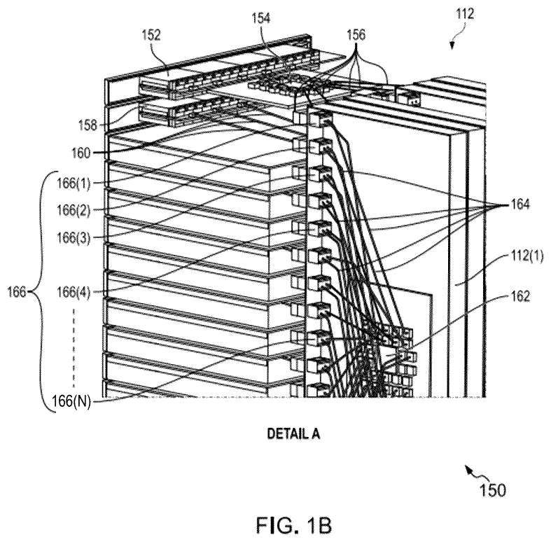

FIG. 1A illustrates a partial perspective view of an assembly (100) (hereinafter also referred to as “the assembly (100)”) of networking and computing hardware assembled in physical infrastructure equipment, in accordance with an embodiment of the present disclosure. In several non-limiting embodiments, the physical infrastructure equipment of the assembly (100) is a rack in an Open Rack (OR) configuration. The OR configuration refers to a specific approach to building data centers and telecommunications infrastructure that emphasizes efficiency, scalability, and openness.

The embodiments of the present disclosure have been explained in reference to an OR configuration rack to emphasize compatibility of the embodiment with the state-of-the-art physical infrastructure. However, a person skilled in the art would appreciate that the embodiments discussed in the following discussion are not restricted to the OR configuration racks alone and are also applicable to all forms of the physical infrastructure used to install networking and computing components in the networking architectures.

The assembly (100) includes a front portion (102) and a rear portion (110). The front portion (102) includes a plurality of forward components (104) (e.g., 104(1), 104(2), 104(3) . . . 104(N), where N is a positive natural number). The plurality of forward components (104) may be of different kinds, for example, compute components, networking components (e.g., line cards), cooling components, cable management components, and other miscellaneous components. The compute components may include servers. Servers are typically housed in sleds or trays that slide horizontally into the physical infrastructure equipment. These sleds can accommodate various server form factors and configurations, including single-socket, dual-socket, and multi-node servers. Other compute components may include Graphics Processing Units (GPUs) and accelerators. The physical infrastructure equipment is envisaged to support the installation of GPUs, Field Programmable Gate Arrays (FPGAs), and other specialized processing units for AI, machine learning, and high-performance computing workloads. These are often installed in dedicated accelerator sleds or directly within server sleds.

The networking components may include line cards. In one or more embodiments, a line card is a pluggable or serviceable hardware module that provides the physical network interfaces and associated packet ingress and egress processing functions. A line card typically includes one or more front-panel ports (e.g., optical or electrical transceivers), port PHYs, MAC and PCS logic, retimers, and optional switch-ASIC elements configured to receive incoming packets from external networks and forward such packets toward a switching fabric for internal routing. The line card may further include local memory buffers, control-plane microcontrollers, power-regulation circuitry, and thermal-management components. In certain embodiments, the line card communicates with one or more fabric cards, enabling scalable aggregate bandwidth as additional line cards are inserted. In Open Compute Project (OCP) and ORV3-compliant architectures, a line card operates as a replaceable unit that expands port density and allows independent servicing or upgrading of interface modules without altering the fabric subsystem or chassis.

In various embodiments, a line card may be implemented as either an active line card or a passthrough line card. An active line card incorporates a switching ASIC, network processor, or forwarding engine that performs packet parsing, lookup, buffering, traffic shaping, and ingress/egress forwarding functions prior to transmission of packet data to the fabric card. Such active line cards may execute programmable pipelines, support local telemetry or monitoring functions, and maintain dedicated high-speed fabric links scaled according to the processing capability of the onboard ASIC. In contrast, a pass-through line card omits the switching ASIC and instead provides a low-latency electrical or optical interconnect path that directly couples the front-panel ports or PHY components to the fabric subsystem. Passthrough line cards may include retimers, serializers/deserializers (SerDes), or signal-integrity conditioning circuitry, but delegate all packet forwarding, lookup, and scheduling functions to the fabric cards or centralized switching elements within the chassis. Both active and passthrough line cards may share the same mechanical form factor and interface standards, and both establish one or more high-speed links to the fabric card for the bidirectional exchange of packet data within the modular switching system.

Continuing with the discission of FIG. 1A, the cooling components may include fans and cooling units. The fans and cooling units may include fans, heat sinks, and liquid cooling systems, to ensure efficient thermal management. Horizontal orientation of the fans is often preferred for general-purpose cooling within the networking architectures, as the fans can be placed strategically to optimize airflow from the front portion (102) to the rear portion (110). However, the vertical orientation of the fans can be used for specific cooling needs, such as exhausting hot air from a particular zone or providing targeted cooling for high-density components. Larger cooling units, such as those used for liquid cooling or rear-door heat exchangers, are typically installed vertically to maximize cooling capacity and airflow efficiency. Smaller cooling units, like fan trays or individual heat sinks, can be installed horizontally to provide targeted cooling for specific components. The other miscellaneous components may include monitoring and management systems to track the health and performance of the equipment, and security devices like firewalls and intrusion detection systems.

The rear portion (110) includes a plurality of fabric cards (112) (e.g., 112(1), 112(2), 112(3) . . . 112(M), where M is a positive natural number). Fabric cards play a crucial role in enabling high-speed communication and connectivity between the line cards within the assembly (100) as well as other components that are external to the assembly. In one or more embodiments, each fabric card (112) is a pluggable hardware module within the assembly (100) that provides the high-bandwidth internal switching fabric used to interconnect multiple line cards or interface modules. The fabric card typically incorporates one or more switch-fabric ASICs, crossbar elements, or packet-forwarding engines configured to receive traffic from each line card and route such traffic to one or more destination line cards. The fabric card may include associated memory, power regulation components, cooling elements, and control circuitry enabling independent management, redundancy, and dynamic load balancing among multiple fabric cards to achieve non-blocking or near non-blocking aggregate throughput. In an Open Compute Project (OCP) or ORV3-compliant architecture, a fabric card operates as a serviceable and replaceable module that scales the network switch's internal bandwidth by adding additional fabric capacity without modifying the line cards or chassis.

The rear portion (110) may further include power shelves (not shown). The power shelves include power supplies and Power Distribution Units (PDUs). The power shelves hold the power supplies that provide power to the equipment in the physical infrastructure equipment. The power supplies connect to the busbars to distribute power efficiently. The PDUs are mounted on the power shelves and provide individual outlets for connecting servers and other devices. The rear portion (110) may further include cooling units such as exhaust fans, heat sinks, liquid cooling systems, rear-door heat exchangers, etc. The rear-door heat exchangers are often mounted on the rear door of the rack. The rear-door heat exchangers use liquid cooling or other methods to remove heat from the exhaust air, improving overall cooling efficiency. Individual fans or fan trays might be located in the rear portion (110) to help expel hot air from the physical infrastructure equipment. The rear portion (110) may further include cable management units such as cable trays and organizers, and strain relief bars. The cable trays and organizers are used to route and organize cables neatly, preventing clutter and improving airflow. The strain relief bars help secure cables and prevent them from being accidentally pulled out. Other components installed in the rear portion (110) may include environmental monitoring sensors for monitoring temperature, humidity, and airflow. Furthermore, in some cases, network connections, such as fiber optic cables or copper Ethernet cables, might enter or exit the physical infrastructure equipment from the rear portion (110).

Traditionally, communication between the line cards and the fabric cards requires several different hardware components, such as cable cartridges, backplanes or midplanes, high-speed buses, switching Application Specific Integrated Circuits (ASICs), crossbar switches, shared memory, and SerDes (Serializer/Deserializer). However, the embodiments disclosed herein include a direct connection between the line cards in the front portion (102) with the plurality of fabric cards (112) in the rear portion (110). It is further envisaged that the line cards in the front portion (102) are orthogonal to the plurality of fabric cards (112) in the rear portion (110), with a perpendicularity tolerance of ±10%. In some embodiments, the perpendicularity tolerance is ±5%. In other words, if the line cards are installed in the horizontal orientation, then the plurality of fabric cards (112) are installed in the vertical orientation and vice versa. FIG. 1A illustrates a portion of the assembly (100) marked as portion ‘A’ which has been discussed in detail in the following discussion.

FIG. 1B illustrates a detailed view (150) of the portion ‘A’ of the assembly (100) of FIG. 1A. The plurality of forward components (104) includes an active line card (152) and a passthrough line card (158). In several embodiments, the active line card (152) and the passthrough line card (158) may be parts of distinct individual network switches. In several alternate embodiments, the active line card (152) and the passthrough line card (158) may be components of a network switch. The other components of the network switches have not been depicted for the sake of clarity. The plurality of forward components (104) includes the active line card (152) and the passthrough line card (158) have been installed horizontally, and the plurality of fabric cards (112) have been installed vertically. Each one of the plurality of fabric cards (112) is directly connected (e.g., directly mating) to one or more of the plurality of forward components (104). In particular, each one of the plurality of fabric cards (112) may be configured to mate with line cards (e.g., active line cars or passthrough line cards) (104). In one or more embodiments, at least one of the plurality of forward components (104) may be installed vertically, and a corresponding fabric card mating with the vertically installed at least one forward component may therefore be installed horizontally to maintain the relative orthogonal orientation.

The relative orthogonal orientation between the line cards and the corresponding fabric cards allows a single fabric card to connect with several line cards, simultaneously, using edge connectors and overlay cables. Therefore, the number of components present in the rear portion (110) is reduced causing a reduction in material costs and lessening of installation complexity that would have arisen from cable cartridges or optical backplanes. Furthermore, in case of greater bandwidths, the configuration of the assembly (100) can be scaled up by installing more fabric cards in parallel to one or more of the plurality of fabric cards (112). Advantages associated with the use of the orthogonal fabric cards with respect to the optical backplanes and cable cartridges also include lower costs of the fabric cards with respect to the optical backplanes and reduced chances of overlay cables getting entangled and becoming difficult to service or replace when compared cables used in cable cartridges.

For example, a first fabric card (112(1)) of the plurality of fabric cards (112), connects with one or more of the plurality of forward components (104) through a plurality of edge connectors (166) (e.g., 166(1), 166(2), 166(3), 166(4) . . . 166(K), where K is a positive natural number). For example, the first fabric card (112(1)) connects with the active line card (152) through a first edge connector (166(1)) and with the passthrough line card (158) with a second edge connector (166(2)).

In one or more embodiments, an edge connector refers to a mechanical and electrical interface formed along an edge region of a printed circuit board (PCB) of a line card, fabric card, or other modular hardware component, the edge connector being configured to mate with a corresponding socket, receptacle, midplane, or backplane interface to establish high-speed signal, power, and control interconnections within a chassis. The edge connector typically includes a plurality of conductive pads, plated contacts, or finger structures arranged in a defined pitch and pattern that support differential signaling, high-bandwidth SerDes channels, management buses, and power delivery rails. When a line card is inserted into a chassis, its edge connector directly engages a corresponding connector associated with a fabric card or intermediate interconnect structure, thereby enabling low-latency, high-integrity transmission of packet data and control signals between the two modules without the need for discrete cabling. The edge connector may further include keying features, grounding structures, mechanical stiffeners, and retention elements to ensure proper alignment, hot-swap capability, and robust signal integrity under thermal and mechanical stress conditions encountered in modular switching systems. In one or more embodiments, the first edge connector (166(1)) and the second edge connector (166(2)) may be selected from a group consisting of High-Speed, High-Density connectors including Peripheral Component Interconnect express (PCIe) edge connectors, high-speed mezzanine connectors, and other custom-built edge connectors. The disclosure is not limited to the aforementioned exemplary edge connectors.

Furthermore, the active line card (152) includes an active ASIC (154) that connects with the first edge connector (166(1)) through a plurality of active overlay cables (156) (e.g., flyover cables). Similarly, the passthrough line card (158) connects physical ports and connectors in a front portion of the passthrough line card (158) with the second edge connector (166(2)) through a plurality of passthrough overlay cables (160). Also, the first fabric card (112(1)), includes a fabric ASIC (162). The fabric ASIC (162) is connected to each one of the plurality of edge connectors (166) through a plurality of fabric overlay cables (164). The use of the plurality of active overlay cables (156) (e.g., flyover cables), the plurality of passthrough overlay cables (160), and the plurality of fabric overlay cables (164) enable direct connection (e.g., direct mating) between the active/passthrough line cards and fabric cards without the need for midplanes or backplanes. Furthermore, distances between adjacent ASICs are significantly reduced and technical barriers imposed by long backplane cabled designs are eliminated. In addition, the passthrough line card (158) enables the assembly (100) to have front-facing only networking ports in the plurality of fabric cards (112), which are easy to use operationally.

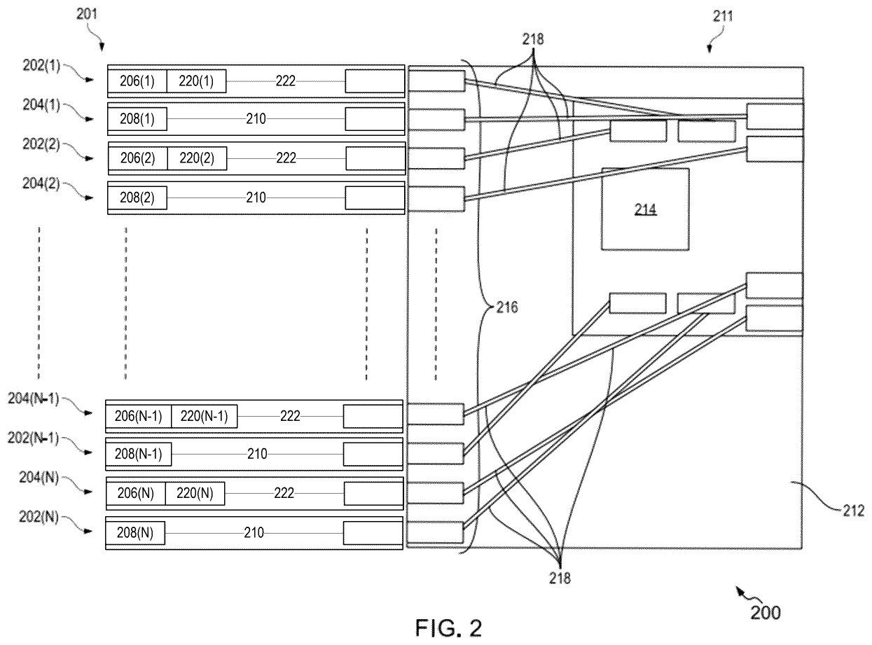

FIG. 2 illustrates a left-side view of an assembly (200) of networking and computing components assembled in physical infrastructure equipment, in accordance with another embodiment of the present disclosure. In several non-limiting embodiments, the physical infrastructure equipment of the assembly (200) is a rack in an Open Rack (OR) configuration. The assembly (200) includes a plurality of active line cards (202(1)), (202(2)) . . . (202(N-1)), (202(N)) and a plurality of passthrough line cards (204(1)), (204(2)) . . . (204(N-1)), (204(N)) in a front portion (201) of the assembly (200).

An active line card (e.g., 202(1)) of the plurality of active line cards and a passthrough line card (e.g., 204(1)) of the plurality of passthrough line cards create a pair, i.e., each pair of line cards comprises one active line card of the plurality of active line cards and one passthrough line card of the plurality of passthrough line cards. In some embodiments, the pairs are disposed over each other, such that the active line cards and passthrough line cards alternate within the assembly (200). That is, an active line card of a first pair of line cards (e.g., 202(1)) is disposed over a passthrough line card of the first pair of line cards (e.g., 204(1)), the passthrough line card of the first pair of line cards (e.g., 204(1)) is disposed over an active line card of a second pair of line cards (e.g., 202(2)), and the active line card of the second pair of line cards (e.g., 202(2)) is disposed over a passthrough line card of the second pair of line cards (e.g., 204(2)). For purposes of this description, the term “disposed over” indicates relative positioning between line cards within the assembly. When the line cards are inserted horizontally, “disposed over” refers to a vertical arrangement, such that one line card is located above another in a stacked configuration. Conversely, when the line cards are inserted vertically, “disposed over” refers to an adjacent positioning along the horizontal axis, meaning one line card is positioned next to another rather than stacked. In both cases, the alternating arrangement of active and passthrough line cards is maintained to form the described pairs within the assembly.

The plurality of active line cards (202(1)), (202(2)) . . . (202(N-1)), (202(N)) include a plurality of respective first networking ports (206(1)), (206(2)) . . . (206(N-1)), (206(N)). The plurality of active line cards (202(1)), (202(2)) . . . (202(N-1)), (202(N)) each includes an active ASIC (220(1)), (220(2)) . . . (220(N-1)), (220(N)) that connects with the plurality of respective first networking ports (206(1)), (206(2)) . . . (206(N-1)), (206(N)) through a plurality of active overlay cables (222) (e.g., flyover cables). The plurality of passthrough line cards (204(1)), (204(2)) . . . (204(N-1)), (206(N)) include a plurality of respective second networking ports (208(1)), (208(2)) . . . (208(N-1)), (208(N)). The plurality of first networking ports (206(1)), (206(2)) . . . (206(N-1)), (206(N)) and the plurality of second networking ports (208(1)), (208(2)) . . . (208(N-1)), (208(N)) may be selected from a group consisting of Ethernet ports (RJ-45 ports for copper Ethernet cables (e.g., Cat5e, Cat6)), fiber optic ports (SFP (Small Form-factor Pluggable) or SFP+ ports for fiber optic cables), coaxial connectors, serial ports, or other specialized interfaces depending upon specific applications.

The plurality of active line cards (202(1)), (202(2)) . . . (202(N-1)), (202(N)), and the plurality of passthrough line cards (204(1)), (204(2)) . . . (204(N-1)), (204(N)) connect with a fabric card (212) in a rear portion (211) of the assembly (200), through a plurality of edge connectors (216). Each one of the plurality of edge connectors (216) is envisaged to include male and female connects. Furthermore, the plurality of edge connectors (216) may be selected from a group consisting of High-Speed, High-Density connectors including Peripheral Component Interconnect express (PCIe) edge connectors, high-speed mezzanine connectors, and other custom-built edge connectors. The plurality of respective first networking ports (206(1)), (206(2)) . . . (206(N-1)), (206(N)) are connected to respective edge connectors of the plurality of edge connectors (216) through active overlay cables (222) (e.g., flyover cables). The fabric card (212) includes a fabric ASIC (214). The fabric ASIC (214) is connected to the plurality of edge connectors (216) through a plurality of fabric overlay cables (218). The plurality of respective second networking ports (208(1)), (208(2)) . . . (208(N-1)), (208(N)) are connected to respective edge connectors of the plurality of edge connectors (216) through passthrough overlay cables (210) (e.g., flyover cables).

The problems discussed throughout this application should be understood as being examples of problems solved by embodiments described herein, and the various embodiments should not be limited to solving the same/similar problems. The disclosed embodiments are broadly applicable to address a range of problems beyond those discussed herein.

Specific embodiments disclosed herein are described in detail with reference to the accompanying figures. In the above detailed description of the embodiments disclosed herein, numerous specific details are set forth in order to provide a more thorough understanding of one or more embodiments disclosed herein. However, it will be apparent to one of ordinary skill in the art that the one or more embodiments disclosed herein may be practiced without these specific details. In other instances, well-known features have not been described in detail to avoid unnecessarily complicating the description.

In the above description of the figures, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment, which may be implemented in addition to, in conjunction with, or in place of the embodiments described with regard to a corresponding like-named component in any other figure.

Throughout this application, elements of figures may be labeled as A to N. As used herein, the aforementioned labeling means that the element may include any number of items, and does not require that the element include the same number of elements as any other item labeled as A to N. For example, a data structure may include a first element labeled as A and a second element labeled as N. This labeling convention means that the data structure may include any number of the elements. A second data structure, also labeled as A to N, may also include any number of elements. The number of elements of the first data structure, and the number of elements of the second data structure, may be the same or different.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

As used herein, the phrase operatively connected, or operative connection, means that there exists between elements/components/devices a direct or indirect connection that allows the elements to interact with one another in some way. For example, the phrase “operatively connected” may refer to any direct connection (e.g., wired directly between two devices or components) or indirect connection (e.g., wired and/or wireless connections between any number of devices or components connecting the operatively connected devices). Thus, any path through which information may travel may be considered an operative connection.

While embodiments discussed herein have been described with respect to a limited number of embodiments, those skilled in the art, having the benefit of this Detailed Description, will appreciate that other embodiments can be devised which do not depart from the scope of embodiments as disclosed herein. Accordingly, the scope of embodiments described herein should be limited only by the attached claims.

What is claimed is:

1. An assembly, comprising:
a plurality of network components located within a front portion of the assembly, wherein the plurality of network components comprises at least one active line card and at least one passthrough line card, wherein the at least one active line card comprises an active Application Specific Integrated Circuit (ASIC);
a fabric card located within a rear portion of the assembly, wherein the plurality of network components is arranged orthogonally to the fabric card within the assembly;
a plurality of first edge connectors, each configured to couple each of the at least one active line cards to the fabric card, wherein the active ASIC is coupled to each of the plurality of first edge connectors via an active overlay cable; and
a plurality of second edge connectors, each configured to couple each of the at least one passthrough line cards to the fabric card, wherein each of the at least one passthrough line cards is coupled to each of the plurality of second edge connectors via a passthrough overlay cable.

2. The assembly of claim 1, wherein the at least one active line card and the at least one passthrough line card are disposed within the front portion of the assembly in an alternating pattern.

3. The assembly of claim 1, wherein the plurality of network components is installed horizontally and the fabric card is installed vertically within the assembly.

4. The assembly of claim 3, wherein an orthogonality between the plurality of network components and the fabric card has a perpendicularity tolerance of ±10%.

5. The assembly of claim 1, wherein the plurality of network components is installed vertically and the fabric card is installed horizontally within the assembly.

6. The assembly of claim 5, wherein an orthogonality between the plurality of network components and the fabric card has a perpendicularity tolerance of ±10%.

7. The assembly of claim 1, wherein the fabric card is directly coupled to the plurality of network components via the plurality of first edge connectors and the plurality of second edge connectors.

8. The assembly of claim 7, wherein the fabric card comprises a fabric ASIC, wherein the fabric ASIC is connected to the plurality first and second edge connectors through a plurality of fabric overlay cables.

9. An assembly, comprising:
a pair of line cards located within a front portion of the assembly, wherein a first line card of the pair comprises an active line card and a second line card of the pair comprises a passthrough line card, wherein the first line card is disposed over the second line card;
a plurality of fabric cards located within a rear portion of the assembly, wherein the pair of line cards is arranged orthogonally to the plurality of fabric cards within the assembly;
a plurality of first edge connectors disposed between the first line card and each of the plurality of fabric cards, wherein each of the plurality of first edge connectors is configured to couple the first line card to the plurality of fabric cards; and
a plurality of second edge connectors disposed between the second line card and each of the plurality of fabric cards, wherein each of the plurality of second edge connectors is configured to couple the second line card to the plurality of fabric cards.

10. The assembly of claim 9, wherein:
the active line card comprises an active Application Specific Integrated Circuit (ASIC);
the active overlay cable couples the active ASIC each of the plurality of first edge connectors; and
the passthrough overlay cable couples the second line card to each of the plurality of second edge connectors.

11. The assembly of claim 9, wherein the pair of line cards is installed horizontally and the plurality of fabric cards is installed vertically within the assembly.

12. The assembly of claim 11, wherein an orthogonality between the pair of line cards and the plurality of fabric cards has a perpendicularity tolerance of ±10%.

13. The assembly of claim 9, wherein the pair of line cards is installed vertically and the plurality of fabric cards is installed horizontally within the assembly, wherein an orthogonality between the pair of line cards and the plurality of fabric cards has a perpendicularity tolerance of ±10%.

14. The assembly of claim 9, wherein each of the plurality of fabric cards comprises a fabric ASIC, wherein the fabric ASIC is connected to the plurality first and second edge connectors through a plurality of fabric overlay cables.

15. The assembly of claim 9, further comprising:
a second pair of line cards located within the front portion of the assembly, wherein:
a first line card of the second pair comprises an active line card and a second line card of the second pair comprises a passthrough line card;
the first line card of the second pair is disposed over the second line card of the second pair; and
the second line card of the pair of line cards is disposed over the first line card of the second pair.

16. The assembly of claim 15, further comprising:
a second plurality of first edge connectors disposed between the first line card of the second pair of line cards and each of the plurality of fabric cards, wherein each of the second plurality of first edge connectors is configured to couple the first line card of the second pair to the plurality of fabric cards; and
a second plurality of second edge connectors disposed between the second line card of the second pair of line cards and each of the plurality of fabric cards, wherein each of the second plurality of second edge connectors is configured to couple the second line card of the second pair to the plurality of fabric cards.

17. The assembly of claim 16, wherein the plurality of fabric cards is directly coupled to the pair of line cards via the plurality of first edge connectors and the plurality of second edge connectors.

18. An assembly, comprising:
one or more pairs of line cards located within a front portion of the assembly, wherein a first line card of each of the one or more pairs is disposed over a second line card of each of the one or more pairs, wherein the one or more pairs of line cards are arranged in parallel;
a plurality of fabric cards located within a rear portion of the assembly, wherein the one or more pairs of line cards are arranged orthogonally to the plurality of fabric cards within the assembly;
a plurality of first edge connectors disposed between the first line card of each of the one or more pairs and each of the plurality of fabric cards, wherein each of the plurality of first edge connectors is directly connected to the first line card to the plurality of fabric cards; and
a plurality of second edge connectors disposed between the second line card of each of the one or more pairs and each of the plurality of fabric cards, wherein each of the plurality of second edge connectors is directly connected to the second line card to the plurality of fabric cards.

19. The assembly of claim 18, wherein the first line card of each of the one or more pairs comprises an active line card and the second line card of each of the one or more pairs comprises a passthrough line card, wherein an active line card comprises an active Application Specific Integrated Circuit (ASIC).

20. The assembly of claim 19, wherein an orthogonality between each of the one or more pairs of line cards and the plurality of fabric cards has a perpendicularity tolerance of ±10%.
